(19) United States
(12) Patent Application Publication
(10) Pub. No.: US 2023/0223402 A1
(43) Pub. Date: Jul. 13, 2023

(54) Three-dimensional Integrated Circuit

(71) Applicant: Kneron Inc., San Diego, CA (US)

(72) Inventors: Oscar Ming Kin Law, San Diego, CA (US); Chun Chen Liu, San Diego, CA (US)

(73) Assignee: Kneron Inc., San Diego, CA (US)

(21) Appl. No.: 17/573,648

(22) Filed: Jan. 12, 2022

(51) Int. Cl. H01L 27/06; H01L 27/02

(52) U.S. Cl. CPC H01L 27/0688; H01L 27/0248; H01L 27/0207

(57) ABSTRACT

A 3D integrated circuit includes a substrate, a first layer on top of the substrate, and a second layer on top of the first layer. The first layer includes a first chip, and a first network bridge formed at a first side of the first chip. The second layer includes a second chip, and a second network bridge formed at a first side of the second chip. The first chip and the first network bridge are coupled to the substrate through bumps. The second chip is coupled to the first chip and the first network bridge through bumps. The second network bridge is coupled to the first network bridge through bumps. The first network bridge and the second network bridge each include a network switch for controlling data transfer and/or power distribution.

### BACKGROUND OF THE INVENTION

### 1. Field of the Invention

The present invention is related to electronic circuits, and more particularly, to a three-dimensional (3D) integrated circuit (IC).

### 2. Description of the Prior Art

Conventional three-dimensional integrated circuit (3D-IC) architectures include a so-called 2.5D architecture and a fully stacked 3D architecture. In a 2.5D architecture, chips are placed side-by-side and interconnected via a horizontal interposer layer. A fully stacked 3D architecture employs chips that are stacked on top of one another. Both architectures use through-silicon vias (TSVs) to connect the metal layers. Compared to 2.5D-IC design, in fully stacked 3D-IC design, chips are connected through bumps and interposers are eliminated. It simplifies the design process and reduces the overall cost.

However, 3D-IC architecture still suffers from some serious drawback. For small changes in IC configurations, the IC layout must be redesigned to provide the feed through channels and allows the signals and power supplies to connect to different chips. For different stack configuration, the IC layouts cannot be reused because the number of the signals and power supplies are varied. The feed through channels form the pyramid shape and occupy significant area in the lower chips, increasing the size and reduces the yield. Moreover, the chips are stacked together, so it is difficult to dissipate heat causing high temperature to significantly degrade overall performance of the IC.

### SUMMARY OF THE INVENTION

An embodiment provides a 3D (three-dimensional) integrated circuit including a substrate, a first layer on top of the substrate, and a second layer on top of the first layer. The first layer includes a first chip, and a first network bridge formed at a first side of the first chip. The second layer includes a second chip, and a second network bridge formed at a first side of the second chip. The first chip and the first network bridge are coupled to the substrate through bumps. The second chip is coupled to the first chip and the first network bridge through bumps. The second network bridge is coupled to the first network bridge through bumps. The first network bridge and the second network bridge each include a network switch for controlling data transfer and/or power distribution.

Another embodiment provides a 3D integrated circuit including a substrate, a first layer on top of the substrate, and a second layer on top of the first layer. The first layer includes a first chip, and a first network bridge formed at a first side of the first chip, and a second network bridge formed at a second side of the first chip opposite to the first side of the first chip. The second layer includes a second chip, a third network bridge formed at a first side of the second chip, and a fourth network bridge formed at a second side of the second chip opposite to the first side of the second chip. The second chip is coupled to the first chip, the first network bridge and the second network bridge through bumps. The first network bridge and the second network bridge each include a network switch for controlling data transfer and/or power distribution.

Another embodiment provides a 3D integrated circuit including a substrate, a plurality of chips on top of the substrate, and a plurality of network bridges on top of the substrate. A chip of the plurality of chips is on top of a network bridge of the plurality of network bridges, and the chip is coupled to the network bridges through bumps. The chip on top of another chip of the plurality of chips, and the chip is couple to the another chip through bumps. Each of the plurality of network bridges includes a network switch for controlling data transfer and/or power distribution.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross sectional view of an example of a 2.5D integrated circuit.

FIG. 2 is a cross sectional view of an example of a fully stacked 3D integrated circuit.

FIG. 3 is a diagram illustrating a plane view of a 3D integrated circuit of an embodiment of the present invention.

FIG. 4 is a diagram illustrating a cross sectional view of the 3D integrated circuit in FIG. 3 along line A-A′.

FIG. 5 is a diagram illustrating a cross sectional view of a 3D integrated circuit of an embodiment of the present invention.

FIG. 6 is a diagram illustrating the network switches in FIGS. 3-4.

FIG. 7 is a diagram illustrating the network switches in FIGS. 3-4 for three-dimensional data transfer.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

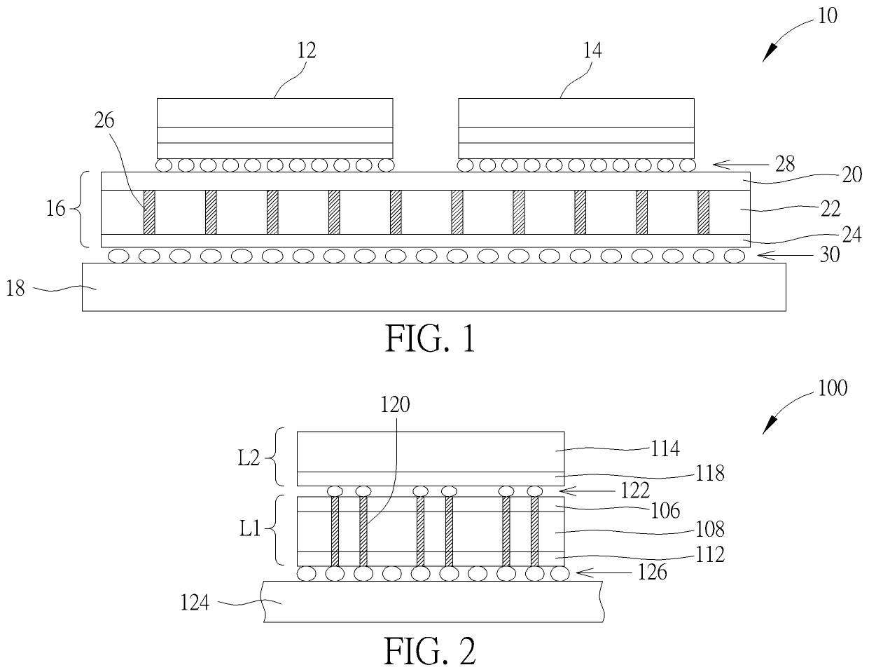

FIG. 1 is a cross sectional view of an example of a 2.5D integrated circuit 10. An interposer 16 is placed between a substrate 18 and chips 12 and 14. The interposer 16 includes a redistribution layers (RDL) 20 and 24, and an interposer substrate 22. The interposer 16 also includes through-silicon vias (TSVs) 26 connecting the redistribution layers 20 and 24 on the upper and lower surfaces. The chips 12 and 14 are coupled to the interposer 16 through bumps 28. The interposer 16 is attached to the substrate 18 through bumps 30. The use of the interposer 16 in 2.5D architectures results in performance loss and increased power consumption and heat generation.

In a fully stacked 3D architecture, multiple chips are stacked together and connected through TSVs (through silicon-vias). This can improve the overall system performance as well as reduce the cost. For example, fully stacked 3D-ICs are seen as a desirable alternative to overcome interconnect scaling issues that can be a major bottleneck on 2.5D ICs. Fully stacked 3D-ICs, with the advantage of a smaller circuit area, reduce the wire length in each layer. Also, TSVs are implemented for vertical interconnect between chips to reduce long cross-chip wiring.

FIG. 2 is a cross sectional view of an example of a fully stacked 3D integrated circuit (3D-IC) 100. The 3D-IC 100 includes a substrate 124, a first layer L1 on top of the substrate 124, and a second layer L2 on top of the first layer L1. The first layer L1 includes a first chip 108 and bumps 126. The first chip 108 includes redistribution layers 106 and 112. The second layer L2 includes a second chip 114 and bumps 122. The second chip 114 includes a redistribution layer 118. In an example, the first chip 108 may include a logic circuit and the second chip 114 may include a memory device. The first chip 108 includes through-silicon vias (TSV) 120 for connecting the redistribution layers 106 and 112 on the upper and lower surfaces. The first chip 108 and the second chip 114 are coupled through bumps 122. The first chip 108 is coupled to the substrate 124 through bumps 126.

Instead of using an interposer for data transfer and power distribution as in 2.5D ICs, the 3D-IC stacks chips directly implement data transfer and power distribution in the intermediate chips. Since the thickness of an individual chip is very small, ideally one could mount as many chips as needed. In practice, however, there are several challenges involved in manufacturing 3D-ICs, which restricts the application of 3D-ICs. For small changes in IC configurations, the IC layout must be redesigned to provide the feed through channels and allows the signals and power supplies to connect to different chips.

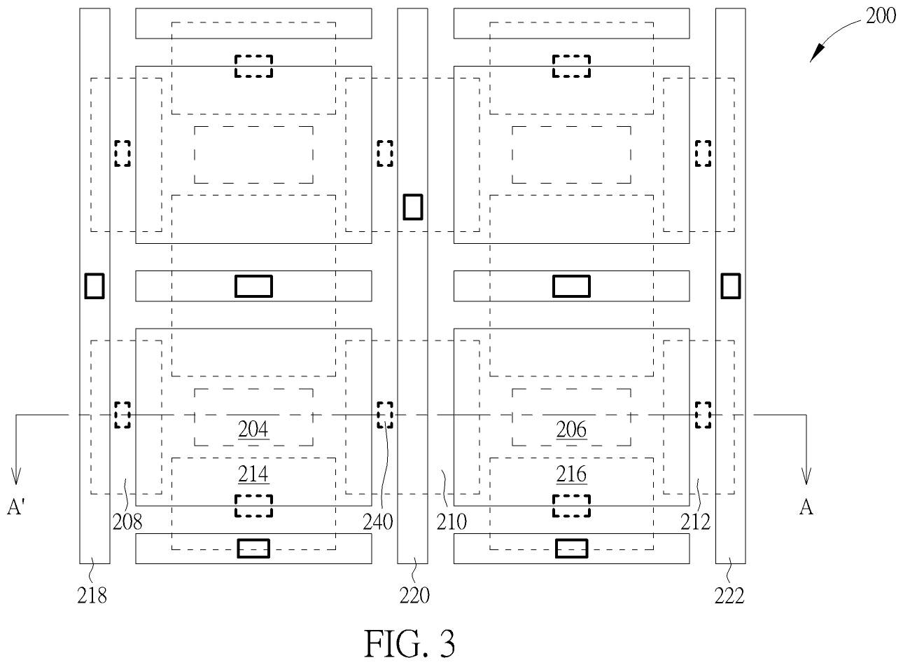

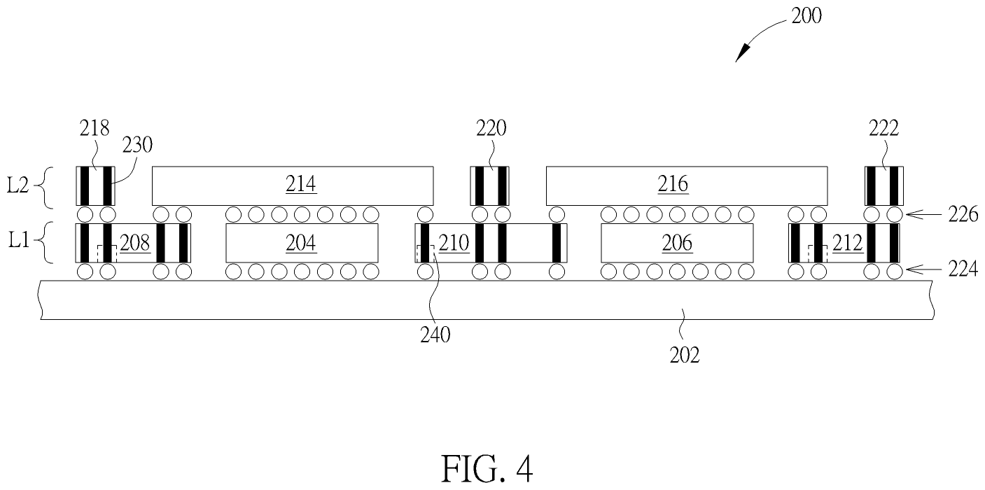

Please refer to both FIGS. 3 and 4. FIG. 3 is a diagram illustrating a plane view of a 3D integrated circuit 200 of an embodiment of the present invention. FIG. 4 is a cross sectional view of the 3D integrated circuit 200 along line A-A′.

The 3D integrated circuit 200 includes a substrate 202, a first layer L1 on top of the substrate 202, and a second layer L2 on top of the first layer L1. The first layer L1 includes chips 204 and 206, and network bridges 208, 210 and 212. The second layer L2 includes chips 214 and 216, and network bridges 218, 220 and 222. The chip 214 is coupled to the chip 204, and the network bridges 208 and 210 through bumps (e.g., solder balls) 226. The chip 216 is coupled to the chip 206, and the network bridges 210 and 212 through bumps 226 with the overlapped region. The overlapped region replaces the interposers in 2.5D-ICs to provide the horizontal connection. Also, the network bridge 218 is coupled to the network bridge 208 through bumps 226; the network bridge 220 is coupled to the network bridge 210 through bumps 226; and the network bridge 222 is coupled to the network bridge 212 through bumps 226. The network bridges 208, 210 and 212 and the chips 204 and 206 are coupled to the substrate 202 through bumps 224 (e.g., solder balls).

In an example, the substrate 202 may be a SiP (System in Package) substrate. The chips 204 and 206 may include logic circuits and the chips 214 and 216 may include memory devices (e.g., registers).

Furthermore, the network bridges 208˜212, 218˜222 may include through-silicon vias (TSVs) 230 to reduce long cross-chip wirings. The network bridges 208˜212, 218˜222 and the chips 204, 206, 214, 216 may include redistribution layers (RDL) on the top surface and/or the bottom surface.

The network bridges 208˜212 and 218˜222 may include network switches 240 (e.g., power control circuit and/or logic switch circuit) for controlling data transfer and/or power distribution. The network switches 240 are coupled to internal wires and can route data and/or power signals in three-dimensions. For example, by controlling the network switches 240, power can be distributed and data can be transferred between the chip 216 and the chip 214 through the network bridge 210. Also, by controlling the network switches 240, power can be distributed and data can be transferred between the chip 204 and the chip 206 through the network bridge 210 and the chips 214, 216. The network switches 240 can be treated as power controllers to support the dynamic voltage scaling and power down mechanism. This architecture without interposers can significantly reduce the length of the power distribution routes to improve heat dissipation. Heat can be transferred more quickly from the center to the edge of the IC package through redistribution layers (RDLs) and through-silicon vias (TSVs). Therefore, this architecture is much simpler than the 3D-IC 100 for thermal management.

In a further example, the network bridges 208 and 210 can act as structural support to allow the larger chip 214 to stack on the smaller chip 204. Moreover, the IC layouts are not required for modification to stack additional layers on the original IC design. Only bumps and RDLs are required to be added for connection of additional layers. This can simplify and accelerate the IC design process.

To explain in more detail, with the network bridges 240, the chip 204 can optionally employ the additional feed through channels for data and/or power distribution. However, the drawback is the larger chip area, high production cost and lower yield. On the other hand, the chip 206 can be fabricated without the TSVs 230. It can rely on the network bridges 240 to support three-dimensional data transfer and/or power distribution. Thus, even without the TSVs 230 in the chip 206, the chip 206 can be integrated in fully stacked 3D-ICs without changes in layout.

The network switches 240 can replace typical crossbar switches in conventional ICs. The data is not limited to two-dimensional (horizontal or vertical) transfer. In fact, the data can be transferred in multiple directions. It can significantly improve the overall data throughput. The same operation can be applied to power distribution. The power can be distributed in multiple directions. Thus, power routing heat dissipation can be made easier.

Moreover, the network switches 240 are not limited only to data transfer and power distribution. It can be implemented to support other functions such as in-memory computing. In the example of in-memory computing, the chip 214 (e.g., memory chip) is stacked on the chip 204 (e.g., logic chip), the network bridges 208 and 210 with the network switches 240 can include cache buffers and act as the memory controller to support the high-speed data transfer. The data from the chip 214 (e.g., memory chip) can be pre-fetched into the network switches 240 for further operations by the chip 204 (e.g., logic chip). The operation results can be temporarily stored in the buffer and then be written back to the chip 214 (e.g., memory chip) later.

In another embodiment, scan chains can be integrated into the network bridges 208˜212 and 218˜222 to test the chips 204, 206, 214, and 216 for KGD (Known Good Die) and examine the chip-to-chip connections to achieve high package yield.

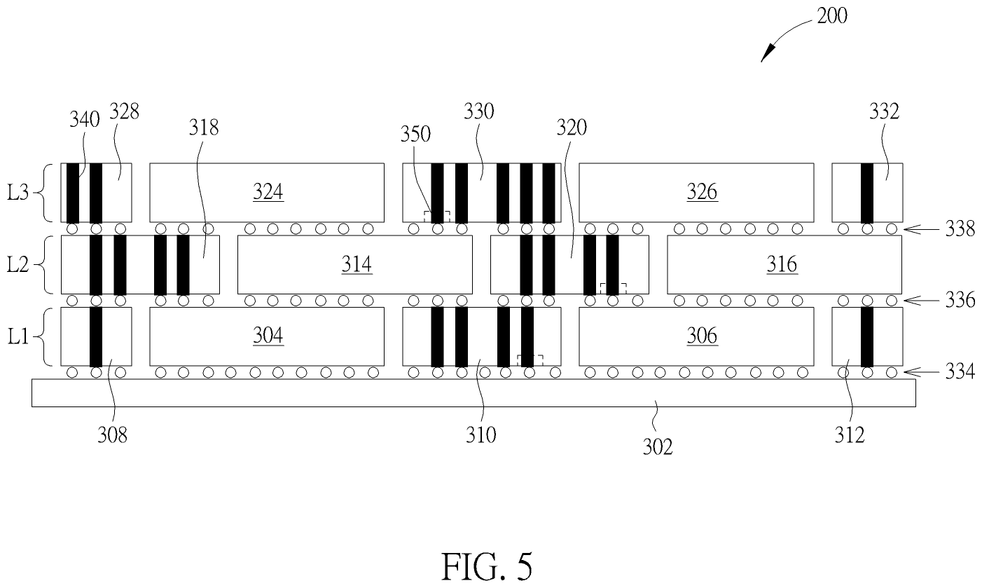

FIG. 5 is a diagram illustrating a cross sectional view of a 3D integrated circuit 300 of an embodiment of the present invention. The 3D integrated circuit 300 includes a substrate 302, a first layer L1 on top of the substrate 302, a second layer L2 on top of the first layer L1, and a third layer L3 on top of the second layer L2. The first layer L1 includes chip 304 and 306, and network bridges 308, 310 and 312. The second layer L2 includes chips 314 and 316, and network bridges 318 and 320. The third layer L3 includes chips 324 and 326, and network bridges 328, 330 and 332.

The chip 304 and 306 and the network bridges 308, 310 and 312 are coupled to the substrate 302 through bumps 334 (e.g., solder balls). The chip 314 is coupled to the chip 304 and the network bridge 310 through bumps 336. The network bridge 320 is coupled to the network bridge 310 and the chip 306 through bumps 336. The network bridge 318 is coupled to the network bridge 308 and the chip 304 through bumps 336. The chip 316 is coupled to the network bridge 312 and the chip 306 through bumps 336. The network bridge 328 is coupled to the network bridge 318 through bumps 338. The chip 324 is coupled to the network bridge 318 and the chip 314 through bumps 338. The network bridge 330 is coupled to the network bridge 320 and the chip 314 through bumps 338. The chip 326 is coupled to the network bridge 320 and the chip 316 through bumps 338. The network bridge 332 is coupled to the chip 316 through bumps 338.

In an example, the substrate 302 may be a SiP (System in Package) substrate. The chips 304, 306, 314 and 316 may include logic circuits and the chips 324 and 326 may include memory devices (e.g., registers).

Furthermore, the network bridges 308˜312, 318˜320 and 328˜332 may include through-silicon vias (TSVs) 340 to reduce long cross-chip wirings. The network bridges 308˜312, 318˜320 and 328˜332 and the chips 304, 306, 314, 316, 324 and 326 may include redistribution layers (RDL) on the top surface and/or the bottom surface.

Each of the network bridges 308˜312, 318˜320, and 328˜332 includes a network switch 350 (e.g., power control circuit and/or logic switch circuit) for controlling data transfer and/or power distribution. The operations of the network switches 350 in the 3D-IC 300 are the similar to those in the 3D-IC 200 and are not repeated herein.

Similar to the 3D-IC 200, the network switches 350 can replace typical crossbar switches in conventional ICs. The data is not limited to two-dimensional (horizontal or vertical) transfer. In fact, the data can be transferred in multiple directions. It can significantly improve the overall data throughput. The same operation can be applied to power distribution. The power can be distributed in multiple directions. Thus, power routing heat dissipation can be made easier.

Also similar to the 3D-IC 200, scan chains can be integrated into the network bridges in the 3D-IC 300 to test the chips for KGD (Known Good Die) and examine the chip-to-chip connections to achieve high package yield.

The architecture of the 3D-IC 300 without interposers can significantly reduce the length of the power distribution routes to improve heat dissipation. Heat can be transferred more quickly from the center to the edge of the IC package through redistribution layers (RDLs) and through-silicon vias (TSVs). Therefore, this architecture is much simpler than the 3D-IC 100 for thermal management.

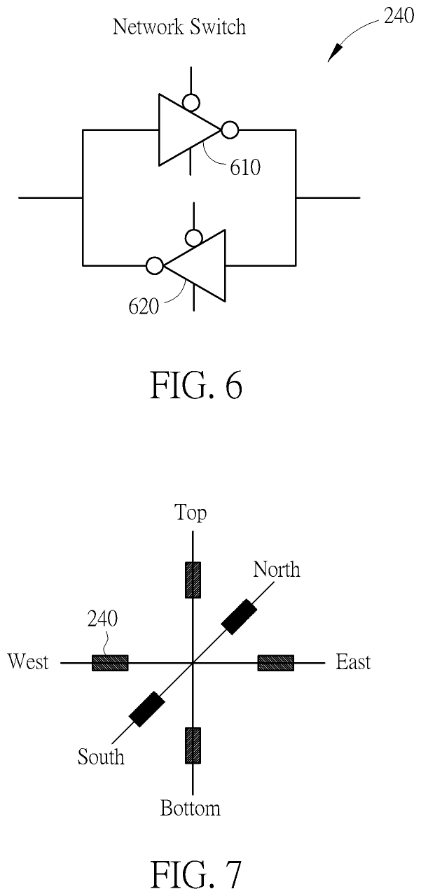

FIG. 6 is an exemplary diagram illustrating the network switches 240 in FIGS. 3˜4. In an example, the network switch 240 may be a pair of cross-coupled gated inverters 610 and 620 which can be programmed dynamically to support various network topologies. The embodiment may also implement other bistable circuits to function as the network switch 240 to control data flow and/or power distribution in three-dimensions. The same circuit configuration can be implemented to the network switch 350 of 3D-IC 300 in FIG. 5 and is not repeated herein.

FIG. 7 is an exemplary diagram illustrating the network switches 240 in FIGS. 3˜4 for three-dimensional data transfer. In the 3D-IC 200, the network switches 240 can control data transfer in six different directions (east, south, west, north, top, and bottom), which corresponds to the x, y, and z axis. With the network switches 240, the data transfer is not limited to horizontal transfer, but the transfer can be three-dimensional, which significantly improves the overall data throughput. The same principle can be applied to the network switch 350 of 3D-IC 300 in FIG. 5 and is not repeated herein.

In summary, new 3D-IC architectures are proposed. The network bridges are overlapped with the chips and provide the horizontal connection through the overlapped regions. The data and power supplies can reach different chips through the network bridge design. The new architecture takes advantages of 3D integrated circuit to allow chips with the same function to stack together. The original IC layouts do not need modifications to add additional layers, because the new layers on top can directly couple to the bottom layer through the bumps and redistribution layers (RDL). The network bridges are not limited only to data transfer and power supply. The network bridges can fully utilize the additional silicon area to incorporate other circuits such as memory controllers, cache or memory buffer, scan chains, power switches, and voltage regulators.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A 3D (three-dimensional) integrated circuit, comprising:
a substrate;
a first layer on top of the substrate, comprising:
a first chip; and
a first network bridge formed at a first side of the first chip; and
a second layer on top of the first layer, comprising:
a second chip; and
a second network bridge formed at a first side of the second chip;
wherein:
the first chip and the first network bridge are coupled to the substrate through bumps;
the second chip is coupled to the first chip and the first network bridge through bumps;
the second network bridge is coupled to the first network bridge through bumps; and
the first network bridge and the second network bridge each comprise a network switch configured to control data transfer and/or power distribution.

2. The 3D integrated circuit of claim 1, wherein the first layer further comprises a third network bridge formed at a second side of the first chip, and the second layer further comprises a fourth network bridge formed at a second side of the second chip, and the third network bridge and the fourth network bridge each comprise a network switch configured to control data transfer and/or power distribution.

3. The 3D integrated circuit of claim 2, wherein the first side of the first chip and the second side of the first chip are opposite sides of the first chip, and the first side of the second chip and the second side of the second chip are opposite sides of the second chip.

4. The 3D integrated circuit of claim 2, wherein the fourth network bridge are coupled to the first chip and the third network bridge through bumps.

5. The 3D integrated circuit of claim 2, wherein the first network bridge, second network bridge, third network bridge, and fourth network bridge each comprise through-silicon vias (TSV).

6. The 3D integrated circuit of claim 2, wherein the first network bridge, second network bridge, third network bridge, and fourth network bridge each comprise scan chains.

7. The 3D integrated circuit of claim 4, further comprising a third layer, comprising:
a third chip;
a fifth network bridge formed at a first side of the third chip; and
a sixth network bridge formed at a second side of the third chip;
wherein:
the third chip is coupled to the second chip and the fourth network bridge through bumps;
the fifth network bridge is coupled to the second chip and the second network bridge through bumps;
the sixth network bridge is coupled to the fourth network bridge through bumps; and
the fifth network bridge and the sixth network bridge each comprises a network switch configured to control data transfer and/or power distribution.

8. The 3D integrated circuit of claim 7, wherein the first side of the third chip and the second side of the third chip are opposite sides of the third chip.

9. The 3D integrated circuit of claim 7, wherein the fifth network bridge and sixth network bridge each comprise through-silicon vias (TSV).

10. A 3D integrated circuit, comprising:
a substrate;
a first layer on top of the substrate, comprising:
a first chip; and
a first network bridge formed at a first side of the first chip; and
a second network bridge formed at a second side of the first chip opposite to the first side of the first chip;
a second layer on top of the first layer, comprising:
a second chip;
a third network bridge formed at a first side of the second chip;
a fourth network bridge formed at a second side of the second chip opposite to the first side of the second chip;
wherein:
the second chip is coupled to the first chip, the first network bridge and the second network bridge through bumps; and
the first network bridge and the second network bridge each comprise a network switch configured to control data transfer and/or power distribution.

11. The 3D integrated circuit of claim 10, wherein the third network bridge is coupled to the first network bridge through bumps, and the fourth network bridge is coupled to the second network bridge through bumps.

12. The 3D integrated circuit of claim 10, wherein the third network bridge and the fourth network bridge each comprise a network switch configured to control data transfer and/or power distribution.

13. The 3D integrated circuit of claim 10, wherein the first network bridge, second network bridge, third network bridge, and fourth network bridge each comprise through-silicon vias (TSV).

14. The 3D integrated circuit of claim 10, wherein the first network bridge, second network bridge, third network bridge, and fourth network bridge each comprise scan chains.

15. A 3D integrated circuit, comprising:
a substrate;
a plurality of chips on top of the substrate;
a plurality of network bridges on top of the substrate;
wherein:
a chip of the plurality of chips is on top of a network bridge of the plurality of network bridges, and the chip is coupled to the network bridges through bumps;
the chip on top of another chip of the plurality of chips, and the chip is couple to the another chip through bumps; and
each of the plurality of network bridges comprises a network switch configured to control data transfer and/or power distribution.

16. The 3D integrated circuit of claim 15, wherein each of the plurality of network bridges comprises through-silicon vias (TSV).

17. The 3D integrated circuit of claim 15, wherein the each of the plurality of network bridges comprises scan chains.

18. The 3D integrated circuit of claim 15, wherein the plurality of network bridges are configured to provide horizontal connections and vertical connections.
